(19) United States
(12) Patent Application Publication
(10) Pub. No.: US 2024/0372518 A1
(43) Pub. Date: Nov. 7, 2024

(54) Compact Balanced Integrated Circuit Amplifier

(71) Applicant: Anokiwave, Inc., San Diego, CA (US)

(72) Inventor: Robert J. McMorrow, Concord, MA (US)

(21) Appl. No.: 18/654,935

(22) Filed: May 3, 2024

Related U.S. Application Data
(60) Provisional application No. 63/463,780, filed on May 3, 2023.

(51) Int. Cl. H03F 3/45

(52) U.S. Cl. CPC H03F 3/45475; H03F 2200/451; H03F 2203/45138

(57) ABSTRACT

Illustrative embodiments provide a compact, integrated circuit quadrature amplifier, with differential inputs and a single-ended output that is smaller than conventional quadrature amplifiers. Preferred embodiments include a quadrature combining apparatus and a corresponding balun apparatus in one small circuit.

### RELATED APPLICATIONS

This application claims priority to U.S. Provisional Application No. 63/463,780, filed May 3, 2023 and titled “Compact Balanced Amplifier for Integrated Circuits” and naming Robert J. McMorrow as inventor [Attorney Docket No. 4181-15201]

The disclosure of each of the foregoing is incorporated herein, in its entirety, by reference.

### TECHNICAL FIELD

The present disclosure relates to amplifiers and, more particularly, to balanced radio frequency amplifiers.

### BACKGROUND ART

Balanced amplifiers offer some systems advantages that make them desirable for many applications. A traditional balanced amplifier uses two parallel paths that amplify the same signal phase shifted by 90-degrees. This is accomplished by adding input and output quadrature couplers to split between the two paths. The use of the output coupler creates several key advantages. First, the reflected wave will directly see the isolation resistor of the quadrature coupler. This results in a very good, broad-band output return loss, something that is poor for most prior art amplifiers. This is especially important in phased array applications where poor isolation between elements and separate power amplifiers (“Pas”) will be exaggerated by any reflected power. This increases the change in voltage standing wave ratio (VSWR) the PAs will see as the relative phase is changed and the beam is steered. In addition to mitigating the impedance changes seen by the PA, the balanced amplifier is more resilient to these changes. This is due to the quadrature nature of the PA match. As the impedance changes, one branch sees this change directly while the other sees this transformed by 90-degrees. If for instance the impedance turns higher than the standard system impedance, one branch will see this new higher impedance while the other will see a proportionally lower impedance. The two branches of the PA will thus distort in different ways and provide some cancellation. This manifests in many ways that are advantageous. Some key linearity metrics that are important included the 1 dB saturation power (OP1dB), Error Vector Magnitude (EVM) distortion, Amplitude-to-Amplitude distortion (AMAM), and Amplitude-to-Phase distortion (AMPM). Of particular interest are the last two metrics, AMAM and AMPM, as this variation makes use of digital pre-distortion (DPD) impractical for phased array systems. An IC-based balanced amplifier solution can be shown to improve all of these metrics by approximately 50%.

Some other advantages of a balanced amplifier in an integrated circuit (IC) setting include second harmonic cancellation. The second harmonic distortion generated in a such an amplifier will be 180-degrees out of phase in the quadrature branches. This noise, or ripple can be particularly prominent in the ground and supply routing on the circuit. This will help clean up the supplies and may reduce the need for excess bypassing capacitance.

In spite of their advantages, balanced amplifiers are rarely used in high volume IC applications. The reasons are due to the increased size and the impact on peak performance. The size can increase by a factor of 2 due to the need for two parallel chains and the area required for the input and output quadrature couplers. The cost impact often does not outweigh the benefits. The peak performance is also impacted due to the transition loss in the quadrature coupler at the output of the PA. This can often add at least 1 dB of loss which reduces the available output power and reduces the efficiency. For most applications the performance under VSWR is not a primary concern. This is either because the VSWR is well controlled, or the probability is heavily weighted towards the nominal design impedance. So, trading off peak performance for improvements at the VSWR extremes is not an attractive option. Phased array applications are an exception where the VSWR can vary continually about 2:1 as the beam is steered. But, for this to be a practical solution both the size and peak performance impacts must be minimized.

### SUMMARY OF VARIOUS EMBODIMENTS

In accordance with an illustrative embodiment, an integrated circuit radio frequency signal amplifier includes: a multi-layer integrated circuit fabricated on a unitary substrate, the multi-layer integrated circuit including a plurality of circuit elements all on the unitary substrate. The plurality of circuit elements include a differential input circuit having a differential input port; a quadrature splitter circuit having a differential input electrically coupled to the differential input port, a first differential output and a second differential output, the quadrature splitter configured to produce an in-phase differential signal on the first differential output and a quadrature differential signal on the second differential output, the quadrature differential signal in quadrature with the in-phase output signal; a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal; and a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal.

The quadrature combiner circuit includes a first differential quadrature combiner input port coupled to the first amplifier differential output to receive the first differential output signal; and a second differential quadrature combiner input port coupled to the second amplifier differential output to receive the second differential output signal; and a differential quadrature combiner output port. The combiner circuit is configured to combine the first differential output signal and the second differential output signal into a single differential combined RF signal. The integrated circuit radio frequency signal amplifier also includes a differential to single-ended output balun having an output balun differential input coupled to the differential quadrature combiner output port to receive the differential combined RF signal, the differential to single-ended output balun configured to produce, from the differential combined RF signal, a single-ended RF output signal, and a single-ended output port in electrical communication with the differential to single-ended output balun to receive the single-ended RF output signal.

In some embodiments, the quadrature splitter circuit further includes a first differential termination output port.

In some embodiments, the combiner circuit further includes a combiner circuit differential termination output port.

In some embodiments, the differential to single-ended output balun is not a transformer.

Some embodiments also include a unitary integrated circuit package, the unitary substrate and the plurality of circuit elements sealed within the unitary integrated circuit package.

In some embodiments, the unitary substrate includes a silicon substrate. In some embodiments, the unitary substrate includes a silicon-on-insulator substrate.

Another embodiment includes a method of processing a differential radiofrequency input signal, which method includes providing integrated circuit radio frequency signal balanced amplifier. Said amplifier includes a multi-layer integrated circuit fabricated on a unitary substrate. The multi-layer integrated circuit includes a plurality of circuit elements all on the unitary substrate, the plurality of circuit elements including: a differential input circuit having a differential input port; a quadrature splitter circuit having a differential input electrically coupled to the differential input port, a first differential output and a second differential output, the quadrature splitter circuit configured to produce an in-phase differential signal on the first differential output and a quadrature differential signal on the second differential output, the in-phase differential signal in quadrature with the direct quadrature signal; a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal; a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal; and a quadrature combiner circuit. The quadrature combiner circuit includes a first differential quadrature combiner input port coupled to the first amplifier differential output to receive the first differential output signal; and a second differential quadrature combiner input port coupled to the second amplifier differential output to receive the second differential output signal; a differential quadrature combiner output port; the quadrature combiner circuit configured to combine the first differential output signal and the second differential output signal into a single differential combined RF signal, and a differential to single-ended output balun having an output balun differential input coupled to the differential quadrature combiner output port to receive the differential combined RF signal, the differential to single-ended output balun configured to produce, from the differential combined RF signal, a single-ended RF output signal. Said circuit also includes a single-ended output port in electrical communication with the differential to single-ended output balun to receive the single-ended RF output signal.

The method further includes coupling an input differential radiofrequency signal to the differential input port of the differential input circuit, to produce, by the differential input circuit, the in-phase differential signal and the quadrature differential signal; amplifying the in-phase differential signal in the first differential amplifier circuit to produce an amplified in-phase differential signal; amplifying the quadrature differential signal in the second differential amplifier circuit to produce an amplified quadrature differential signal; coupling the amplified in-phase differential signal to the combiner circuit, and coupling the amplified quadrature differential signal the combiner circuit to produce, by the combiner circuit, a single-ended RF output signal.

In some embodiments, the method further includes processing the input differential radiofrequency signal with digital predistortion prior to coupling the input differential radiofrequency signal to the differential input port of the differential input circuit.

In some embodiments, the quadrature splitter circuit further includes a first differential termination output port.

In some embodiments, the combiner circuit further includes a combiner circuit differential termination output port.

In some embodiments, the differential to single-ended output balun is not a transformer.

In some embodiments, the integrated circuit radio frequency signal amplifier is sealed within a single unitary integrated circuit package.

In some embodiments, the unitary substrate includes a silicon substrate. In some embodiments, the unitary substrate includes a silicon-on-insulator substrate.

Yet another embodiment includes a multi-layer integrated circuit fabricated on a unitary substrate, the multi-layer integrated circuit including a plurality of circuit elements all on the unitary substrate. The plurality of circuit elements include a differential input circuit having a differential input port; a quadrature splitter circuit having a differential input electrically coupled to the differential input port, a first differential output and a second differential output, the quadrature splitter circuit integrated on a plurality of layers of the multi-layer integrated circuit and configured to produce an in-phase differential signal on the first differential output and a quadrature differential signal on the second differential output, the quadrature differential signal in quadrature with the in-phase output signal; a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal; a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal; and combiner means for producing a single differential combined RF signal from the first differential output signal and the second differential output signal. The apparatus also include means for producing, from the differential combined RF signal, a single-ended RF output signal; and a single-ended output port in electrical communication with the differential to single-ended output balun to receive the single-ended RF output signal.

In some embodiments, the means for producing, from the differential combined RF signal, a single-ended RF output signal is not a transformer.

In some embodiments, the quadrature combiner means includes a first differential termination output port.

In some embodiments, the unitary substrate includes a silicon substrate.

In some embodiments, the unitary substrate and the multi-layer integrated circuit are sealed within a single unitary integrated circuit package.

### BRIEF DESCRIPTION OF THE DRAWINGS

The foregoing features of embodiments will be more readily understood by reference to the following detailed description, taken with reference to the accompanying drawings, in which:

FIG. 1A schematically illustrates a conventional balanced amplifier;

FIG. 1B illustrates an embodiment of conventional a balun;

FIG. 1C illustrates an embodiment of a conventional coupled line structure;

FIG. 1D illustrates an embodiment of a conventional quadrature circuit made to accommodate differential signals;

FIG. 2A schematically illustrates an embodiment of a compact balanced integrated circuit differential amplifier according to an illustrative embodiment;

FIG. 2B schematically illustrates an embodiment of a compact balanced integrated circuit differential amplifier in an according to an integrated circuit package according to an illustrative embodiment;

FIG. 3A schematically illustrates an embodiment of a quadrature combiner circuit;

FIG. 3B schematically illustrates a side cutaway view of an embodiment of an integrated circuit balanced amplifier;

FIG. 3C schematically illustrates traces on an embodiment of circuit traces of a first trace layer of an embodiment of an integrated circuit balanced amplifier;

FIG. 3D schematically illustrates an embodiment of vias extending from traces on a first trace layer to traces on the second trace layer of an embodiment of an integrated circuit balanced amplifier;

FIG. 3E schematically illustrates an embodiment of circuit traces on a second trace layer of an embodiment of an integrated circuit balanced amplifier;

FIG. 3F schematically illustrates an embodiment of circuit traces on a third trace layer of an embodiment of an integrated circuit balanced amplifier;

FIG. 3G schematically illustrates an embodiment of vias extending from traces on a third trace layer to traces on the fourth trace layer of an embodiment of an integrated circuit balanced amplifier;

FIG. 3H schematically illustrates an embodiment of circuit traces on a fourth trace layer of an embodiment of an integrated circuit balanced amplifier.

FIG. 4 schematically illustrates an embodiment of a quadrature combiner circuit;

FIG. 5A, FIG. 5B, FIG. 5C, and FIG. 5D show small-signal S-parameter performance for an embodiment of the quadrature combiner;

FIG. 6 is a flowchart illustrating a method for processing a differential radiofrequency input signal.

### DETAILED DESCRIPTION OF ILLUSTRATIVE EMBODIMENTS

Illustrative embodiments provide a compact, integrated circuit quadrature amplifier, with differential inputs and a single-ended output that is smaller than conventional quadrature amplifiers. Preferred embodiments include a quadrature combining apparatus and a balance-unbalanced (“balun”) apparatus in one small circuit. Illustrative embodiments have a quadrature combiner that has both a compact size, and a loss of only about 0.5-0.8 dB.

In illustrative integrated circuit embodiments, the amplifier branches remain differential and avoid many of the problems with ground and supply parasitics. The balanced amplifier has an additional benefit in that the second harmonic signals which are normally still a problem with differential circuits are 180-degrees out of phase and cancel.

The size of the integrated circuit quadrature amplifier is restrained in part by configuring traces on metal layers to have more capacitance between traces than in conventional quadrature combiner circuit configurations. Capacitance is created by both edge coupling between traces on the same integrated circuit layer, and broadside coupling between a first trace on a first integrated circuit layer and a second trace on a second integrated circuit layer, for example where the first trace is directly above or below the second trace when the first integrated circuit layer and the second integrated circuit layer are parallel to one another, such that a straight line normal to a planar surface of a first integrated circuit layer and passing through the first trace would also pass through the second trace.

One way to create capacitance, in illustrative embodiments, is to use broadside coupling where the two traces are on top of each other on different metal layers separated by a thin dielectric. This mode of coupling adds more capacitance than the more conventional edge coupling and helps reduce the length needed to create a quarter-wave shift.

These broadside coupled traces can then be configured into a coil (or spiral) layout with 1 or more turns, which configuration will create edge coupling between the positive and negative sides to help enforce balance in amplitude and phase.

Some integrated circuits employ a differential architecture. This is done to minimize the impact of ground impedance which can be substantial and difficult to control. Differential circuits create a virtual ground where the positive and negative sides meet which can be a very low impedance resulting in higher gain.

One element at the output end of embodiments of an amplifier circuit is the balun, which converts the differential signal into a single sided one referenced to ground for the IC output. This is usually the final stage in the amplifier chain.

Illustrative embodiments reduce changes in linearity due to a varying load impedance, improve EVM distortion vs. varying load impedance (VSWR), and improve AMAM and AMPM distortion due to changes in VSWR.

Some embodiments combine embodiments of a balanced amplifier with digital predistortion (DPD), which improves the linear power for balanced amplifier, and improves efficiency.

Using a balanced amplifier provides a more stable DPD solution into a varying load impedance (VSWR).

Definitions: As used in this description and the accompanying claims, the following terms shall have the meanings indicated, unless the context otherwise requires.

The term “differential,” in reference to an electrical signal, means a signal having two components, referred to the “positive” and “negative” component, as known in the art.

The term “differential,” in reference to an electrical circuit or circuit element, means a circuit or circuit element having two conductors (e.g., traces), one for the “positive” component of a differential signal and one for the “negative” component of the differential signal.

The term “quadrature,” describing a radio-frequency electrical signal, means that the radio-frequency electrical signal has a phase of 90 degrees relative to another signal which may be referred-to as the “in-phase” signal;

The term “radio-frequency” (or “RF”) in reference to an electrical signal means a frequency greater than 1 gigahertz (“GHz”) and up to 300 GHz. In some embodiments, the term “radio-frequency” (or “RF”) means a frequency of greater than 3 gigahertz (“GHz”) and up to 100 GHz. In some embodiments, the term “target radio-frequency” (or “target RF”) means a frequency of greater than 8 gigahertz (“GHz”) and up to 80 GHz.

A “set” includes at least one member.

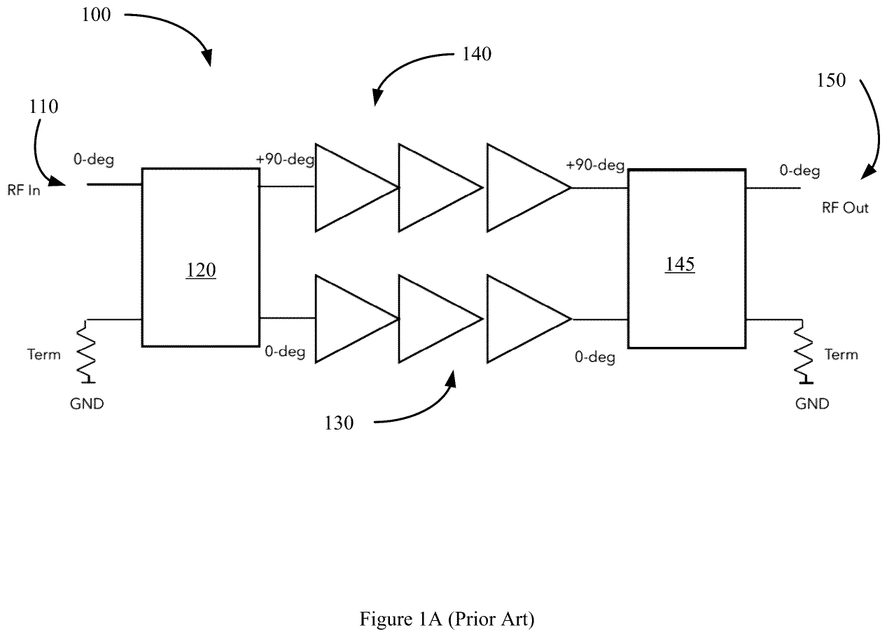

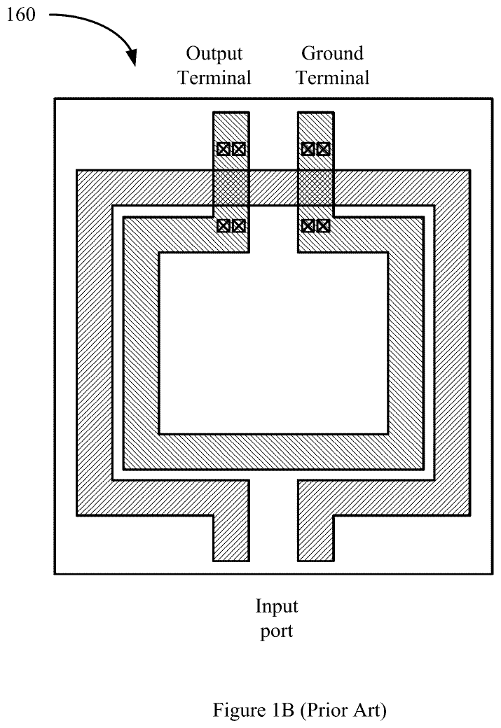

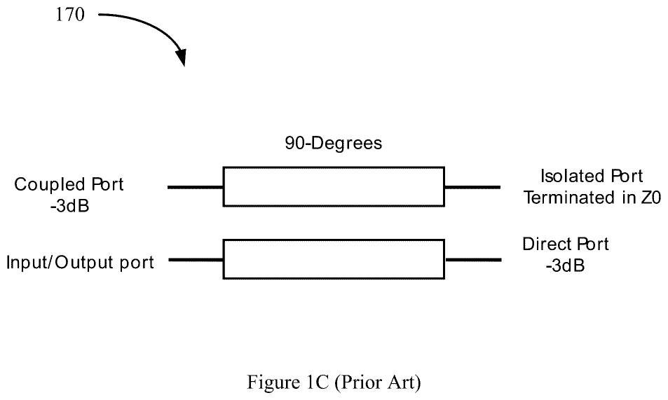

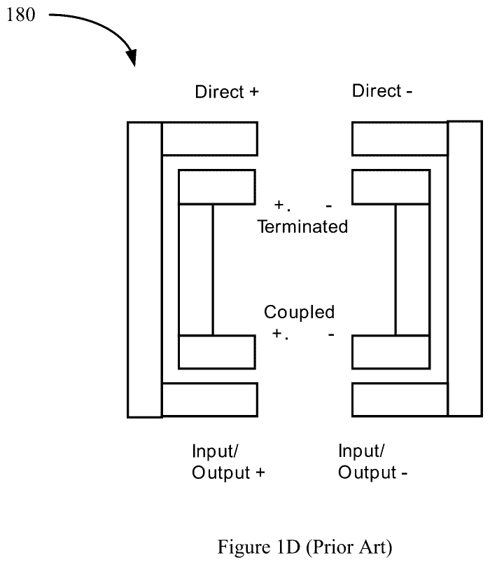

FIG. 1A schematically illustrates a conventional balanced amplifier 100, which has a single-ended input (i.e., not a differential input), and which operates on a single-ended signal through phase shift circuit 120, amplifier circuits channels 130 and 140, and combiner circuit 145, and which produces a single-ended output signal at terminal 150. The conventional balanced amplifier 100 is implemented using a plurality of hybrid circuits, each of which is packaged separately from other circuits as known in the art. Such a hybrid circuit may include, for example, a combiner in one package, and an associate balun in a different package. For purposes of the present application, an apparatus having separate integrated circuits mechanically bonded to a common substrate is not a circuit having a unitary substrate.

FIG. 1B illustrates an embodiment of a prior art balun 160.

FIG. 1C illustrates an embodiment of a coupled line structure 170 using quarter-wave lines. Quarter-wave lines are quite large, however, and impractical for use in an integrated circuit. Moreover, if used as a coupler, the coupled line structure 170 presents a disadvantage in that it is single-ended, so a differential coupler would require two such coupled line structures 170, undesirably making such a differential coupler, and the circuit in which it is used, undesirably even larger.

Such coupled line structures 170 are defined, at least in part, by their phase shift, odd-mode character impedance, and even-mode characteristic impedance. Typical coupled line structures 170 also induce inductive coupling; a classic quadrature circuit uses magnetic (inductive) and capacitive coupling that helps set the characteristic impedance. Adding capacitance to a coupled line structure 170 reduces the length need to generate a desired coupling, but at the cost of reducing bandwidth.

FIG. 1D illustrates an embodiment of a conventional quadrature circuit in which two coupled line structures 170 are used in a differential manner. As compared to circuit having only a single coupled line structure 170, a differential coupler would require two such coupled line structures, undesirably making such a differential coupler, and the circuit in which it is used, undesirably even larger.

Moreover, if used as a coupler the coupled line structure 180 presents a disadvantage in that in that it is single-ended, so a differential coupler would require two such coupled line structured 180, undesirably making such a differential coupler, and the circuit in which it is used, undesirable even larger.

Moreover, in addition to suffering from a size that is still larger than desired, a coupled line structure 180, particularly when used as a quadrature combiner, also suffers poor alignment between the positive and negative sides. Differential signals on an IC can skew out of phase or amplitude resulting in undesired common mode signals. For this reason, illustrative embodiments use coupled line wave guides to keep the amplitude and phase balance in check, and also add coupling between the positive and negative sides. A way to achieve coupling between the positive and negative sides is by adding a second form of coupling to the circuit.

While some conventional differential quadrature combiners used edge (or “side”) coupling with the two lines running parallel, illustrative embodiments also employ broadside coupling (i.e., where the two lines or traces are on top of each other on different metal layers separated by a thin dielectric). This mode of coupling has the added advantage of providing extra capacitance to help reduce the needed trace length. Such broadside coupled traces can then be configured into a coil, or spiral, shape with 1 or more turns. Such a coiled, or spiral, configuration reduces the space occupied by the combiner apparatus relative to conventional combiner circuits.

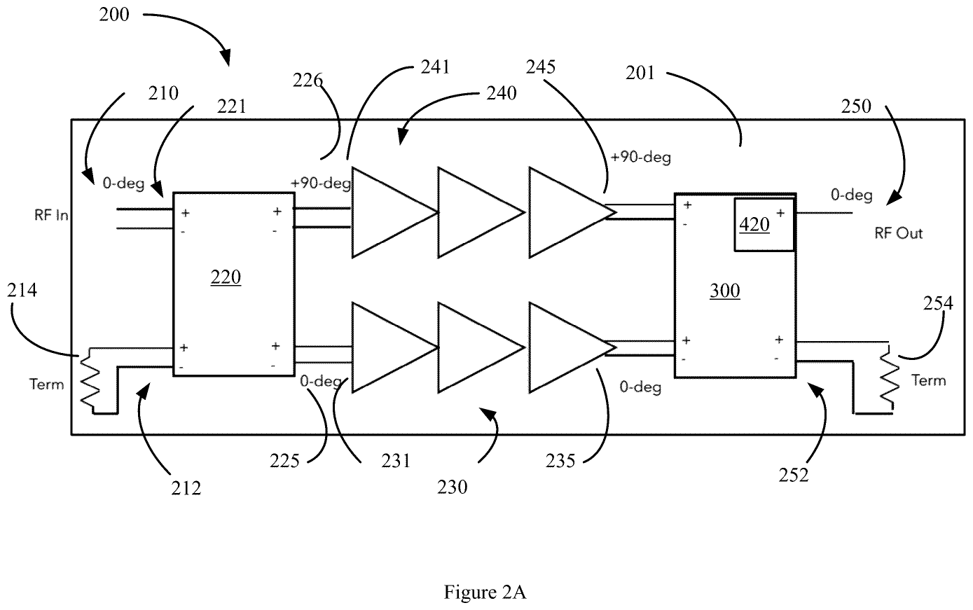

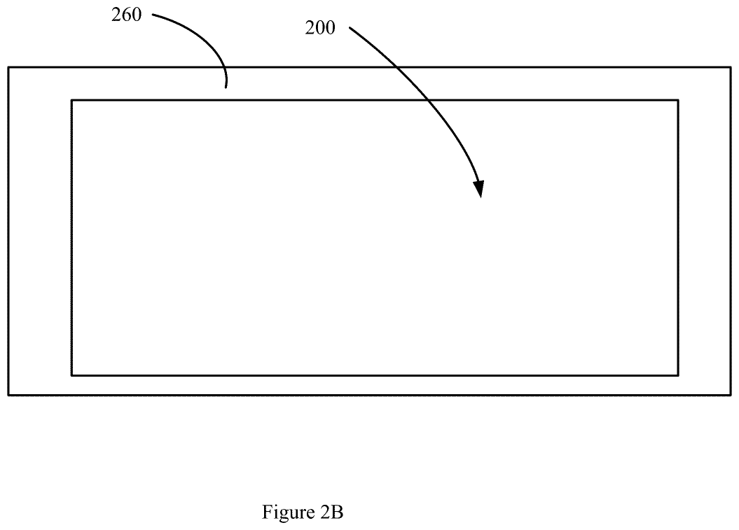

FIG. 2A schematically illustrates an embodiment of a compact balanced integrated circuit differential amplifier 200 according to an illustrative embodiment.

In preferred embodiments, the circuit elements of the compact balanced integrated circuit differential amplifier 200 are all integrated in a single integrated circuit having unitary semiconductor substrate, and are not composed of a plurality of separate integrated circuits (even if such separated integrated circuits are together in a single package, or mounted on a common substrate). In illustrative embodiments, the compact balanced integrated circuit differential amplifier 200 are all integrated in a single integrated circuit by lithography performed on the unitary semiconductor substrate. In some embodiments, the unitary semiconductor substrate may be mounted to an insulator substrate 310 to form a “silicon-on-insulator” integrated circuit, in which the insulator substrate 310 is not part of a package in which the compact balanced integrated circuit differential amplifier 200 is packaged.

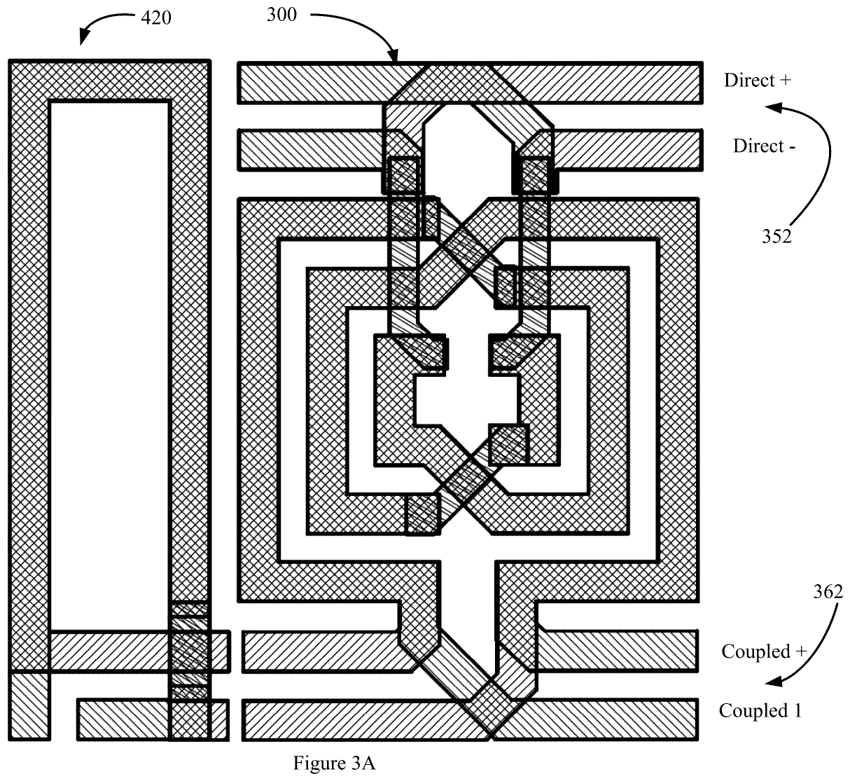

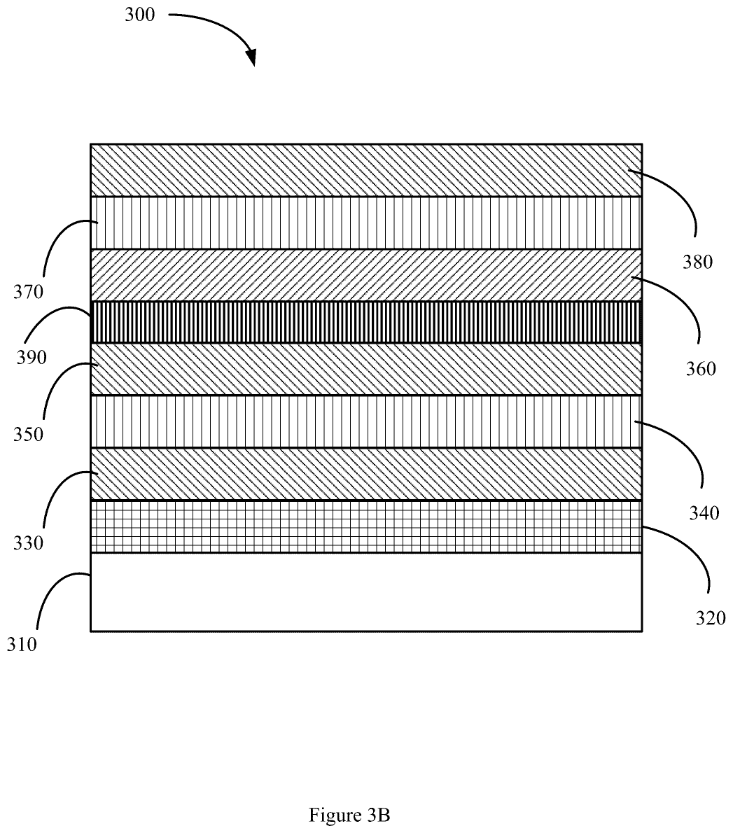

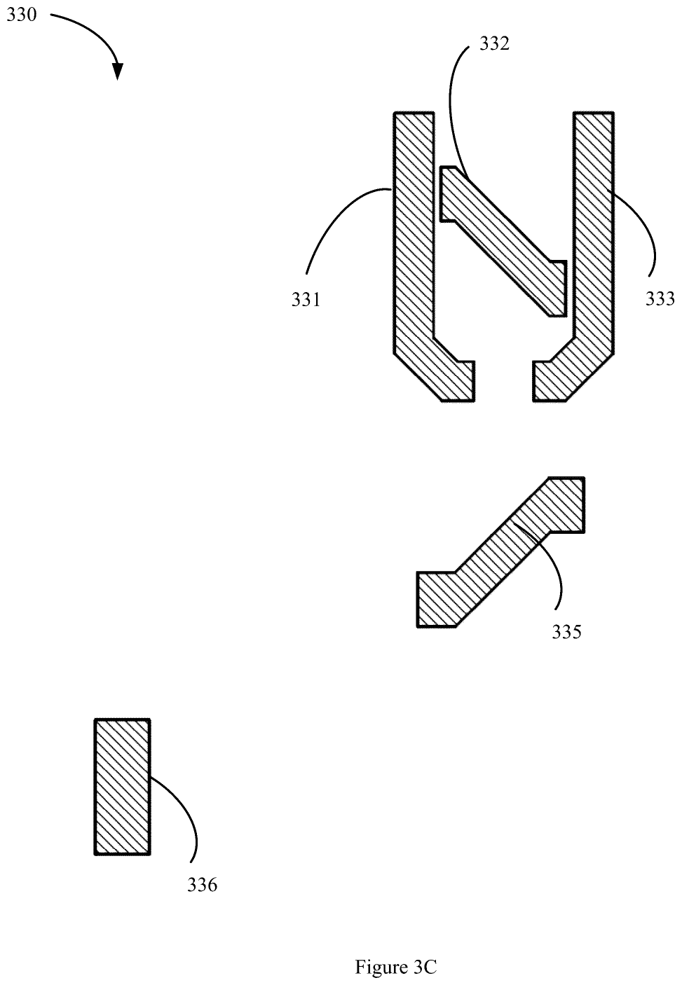

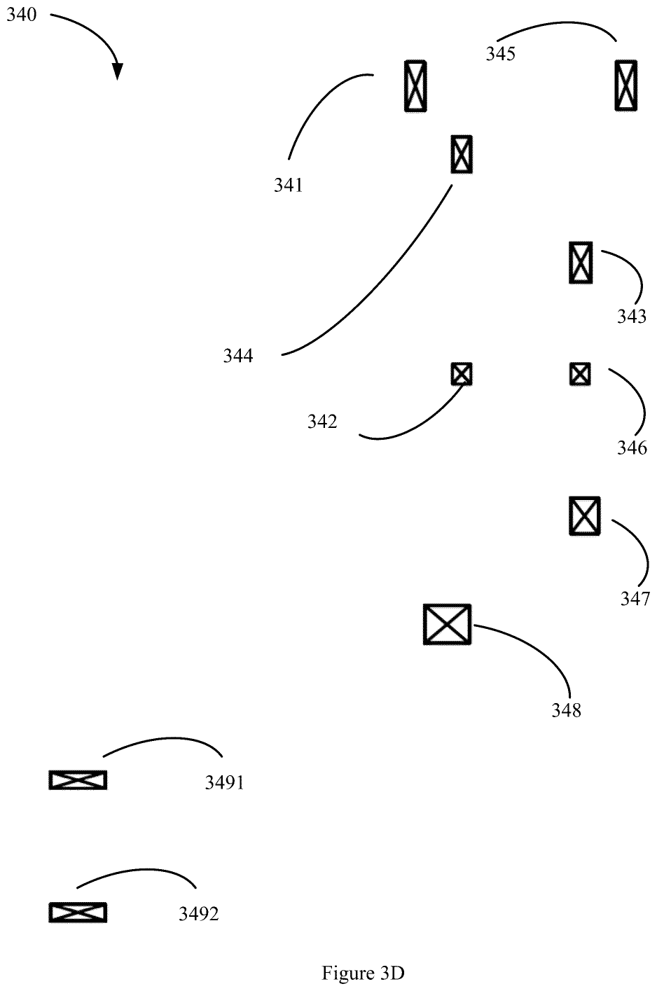

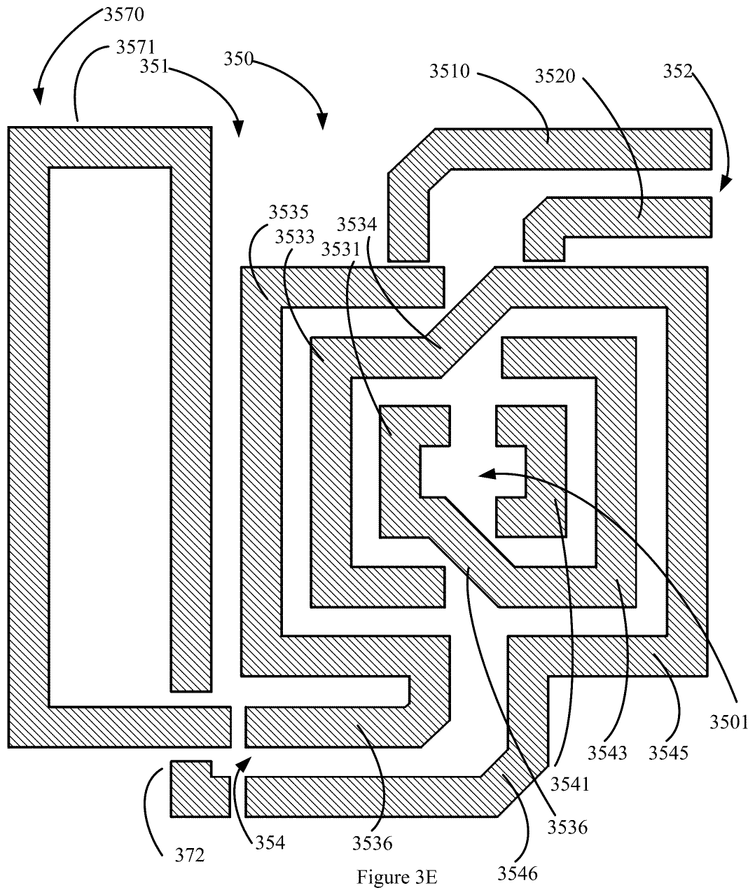

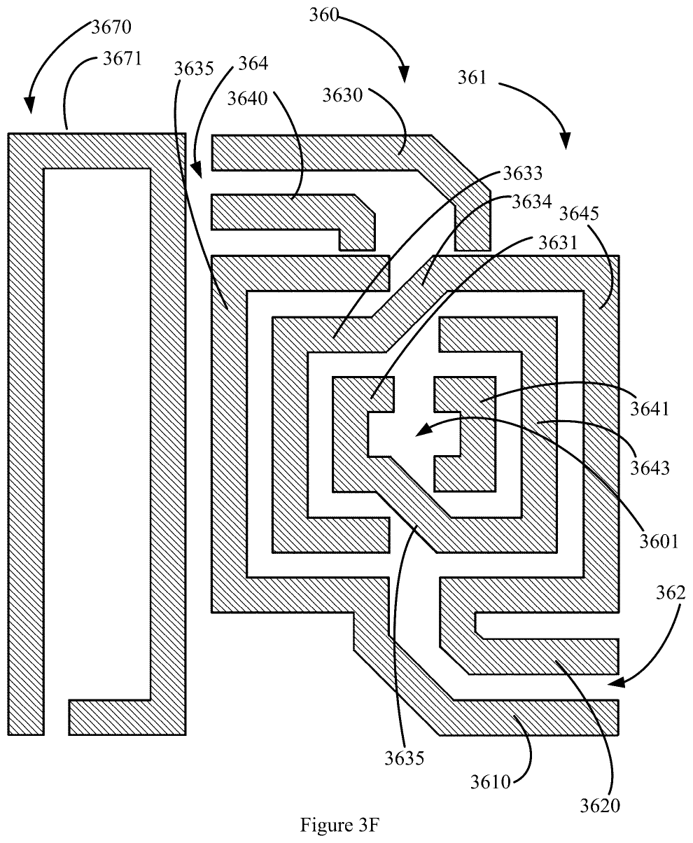

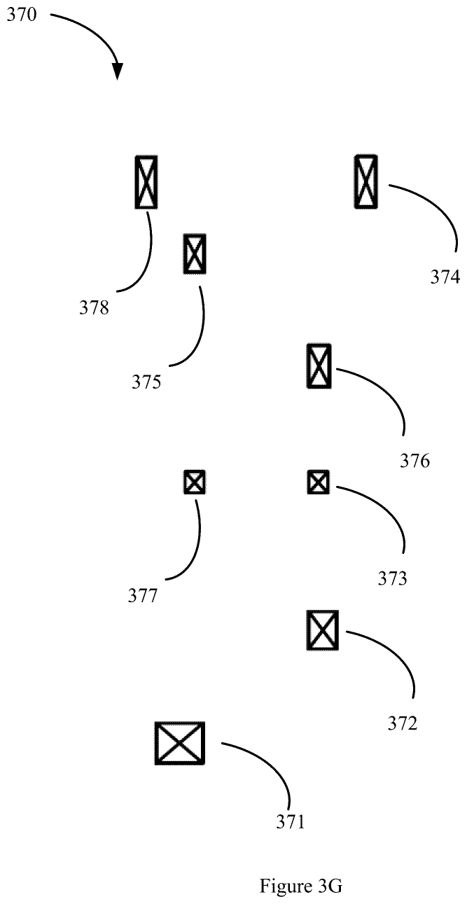

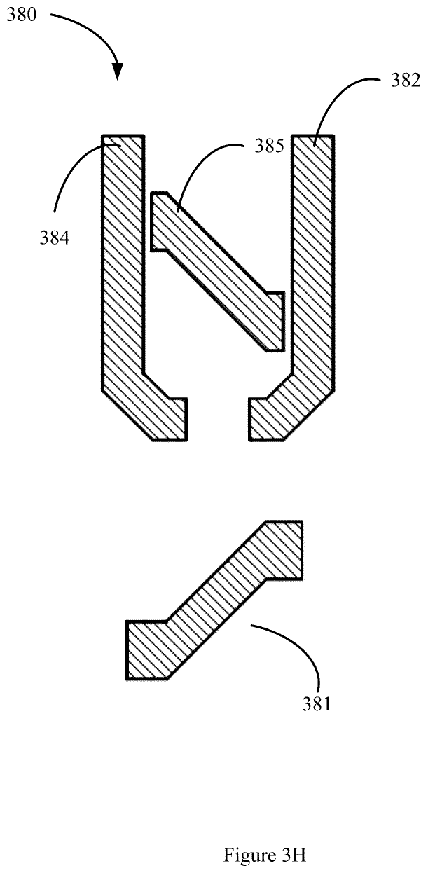

The compact balanced integrated circuit differential amplifier 200 includes a multi-layer integrated circuit fabricated on or in the unitary substrate. The multi-layer integrated circuit includes a plurality of circuit elements all on the unitary substrate. An embodiment of a multi-layer integrated circuit quadrature combiner and balun fabricated on or in the unitary substrate is schematically illustrated in FIG. 3A, FIG. 3B, FIG. 3D, FIG. 3E, FIG. 3F, FIG. 3G and FIG. 3H.

Referring to FIG. 2A, the circuit elements of an embodiment of a compact balanced integrated circuit differential amplifier 200 include a differential input port 210 configure to receive a differential RF input signal.

The compact balanced integrated circuit differential amplifier 200 also includes a quadrature splitter circuit 220 having a differential input 221 electrically coupled to the differential input port 210, and having a first differential output 225 to produce an in-phase signal and a second differential output 225 to produce a quadrature signal. In illustrative embodiments of balanced amplifiers as disclosed herein, operational parameters of the quadrature splitter circuit (e.g., at an input end of a balanced amplifier system) are not as critical as operational parameters for a quadrature combiner circuit. Consequently, in some embodiments, quadrature splitter circuit 220 may be a conventional quadrature splitter circuit as known in the art.

In illustrative embodiments, the quadrature circuit 220 also includes an input quadrature circuit terminal or first differential termination output port which, in illustrative embodiments, may be loaded with an input terminal load 214.

The compact balanced integrated circuit differential amplifier 200 is configured to produce an in-phase (or “direct”) differential signal on the first differential output 225 and a quadrature (or “coupled”) differential signal on the second differential output 226 wherein the coupled differential signal is in quadrature with the direct output signal.

The compact balanced integrated circuit differential amplifier 200 also includes a first differential amplifier circuit 230 having a first amplifier differential input 231 in electrical communication with the first differential output 225 of the quadrature circuit 220, and a first amplifier differential output 235. The first differential amplifier circuit 230 is configured to produce, at the first amplifier differential output 235, a first differential output signal.

‘The first differential amplifier circuit 230 may be a single amplifier, or a set of two or more amplifiers stages cascaded in series.

The compact balanced integrated circuit differential amplifier 200 also includes a second differential amplifier circuit 240 having a second amplifier differential input 241 in electrical communication with the second differential output 226 of the quadrature circuit 220, and a second amplifier differential output 245. The second differential amplifier circuit 240 is configured to produce, at the second amplifier differential output 245, a second differential output signal in quadrature with the first differential output signal.

The second differential amplifier circuit 240 may be a single amplifier, or a set of two or more amplifiers stages cascaded in series.

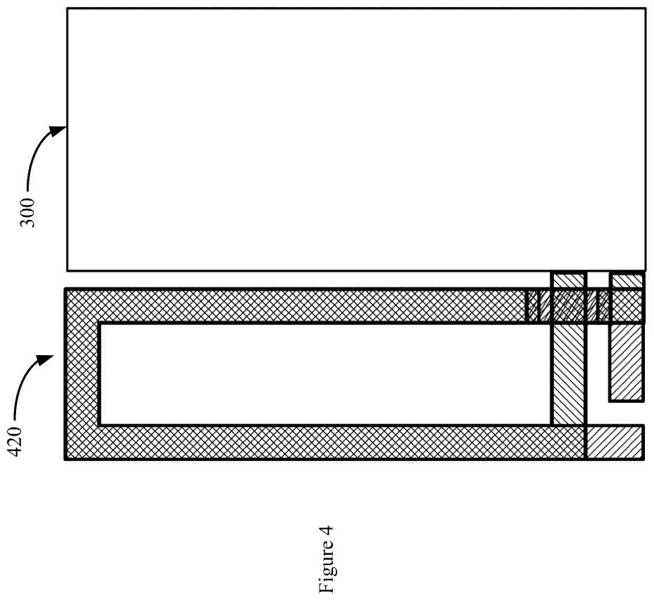

The compact balanced integrated circuit differential amplifier 200 also includes a quadrature combiner circuit 300 (FIG. 3A; FIG. 4) as describe herein and configured to operate on the first differential output signal and the second differential output signal into a single differential combined RF signal.

FIG. 2B schematically illustrates an embodiment of a compact balanced integrated circuit differential amplifier 200 in an integrated circuit package 260 according to an illustrative embodiment. In some embodiments, the circuit package 260 may be a plastic package as known in the art, such as a package having a leadframe which the compact balanced integrated circuit 200 differential amplifier is supported and over which packaging plastic is flowed. In some embodiments, the circuit package 260 may be a ball grid array package as known in the art.

In preferred embodiments, the package 260 is not a multi-chip module, and is not a hybrid package as known in the art.

FIG. 3A schematically illustrates an embodiment of a quadrature circuit 300. The quadrature circuit 300 includes a plurality of traces on a plurality of layers of a unitary semiconductor substrate 320. Each layer of the plurality of layers has a first surface, and a second surface opposite to and parallel to the first surface. The features of the quadrature circuit 300 are shown in more detail in FIG. 3B, FIG. 3C, FIG. 3D, FIG. 3E, FIG. 3F, FIG. 3G and FIG. 3H, but to avoid cluttering FIG. 3A, some features are omitted from FIG. 3A. The quadrature combiner circuit 300 may be considered to include an output balun 420, as schematically illustrated in FIG. 4. The quadrature combiner circuit 300 and output balun 420 may be referred-to, collectively, as a quadrature output circuit.

In some embodiments, a trace (e.g., a first trace) on a layer of the unitary semiconductor substrate maybe broadside coupled to another trace (e.g., a second trace) on another layer of the unitary semiconductor substrate. Such broadside coupling introduces capacitance between the first trace and the second trace, which coupling allows the quadrature combiner circuit 300 to be smaller than it would be without such capacitance, thereby reducing the size of the quadrature combiner circuit 300 and making the compact balanced integrated circuit differential amplifier 200 more compact than it would have been without such broadside coupling.

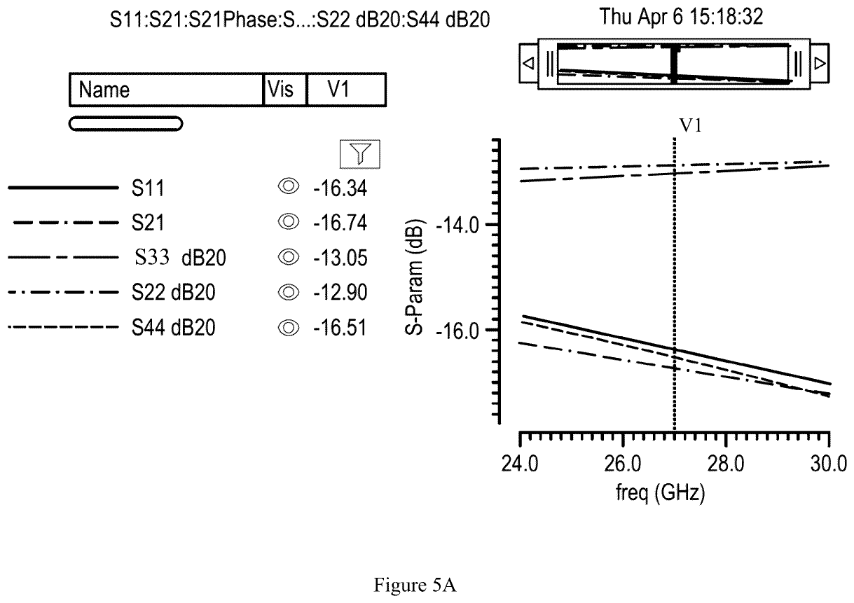

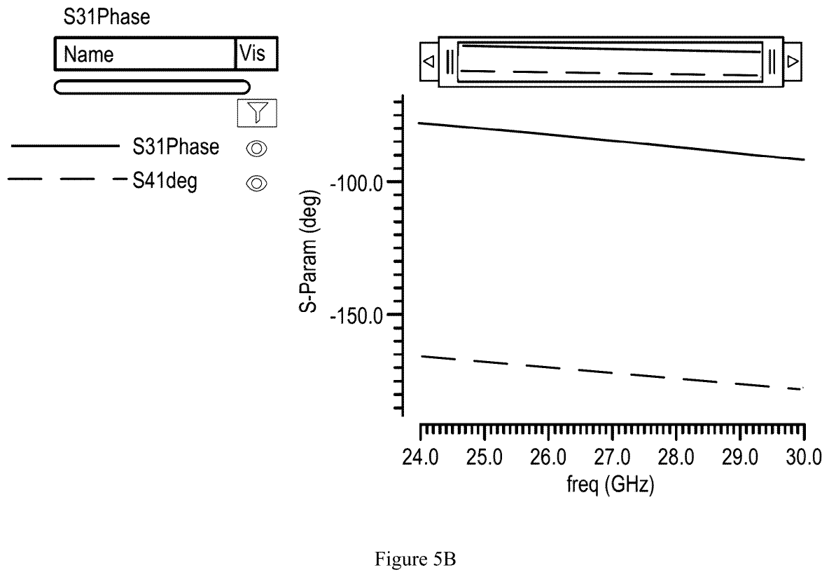

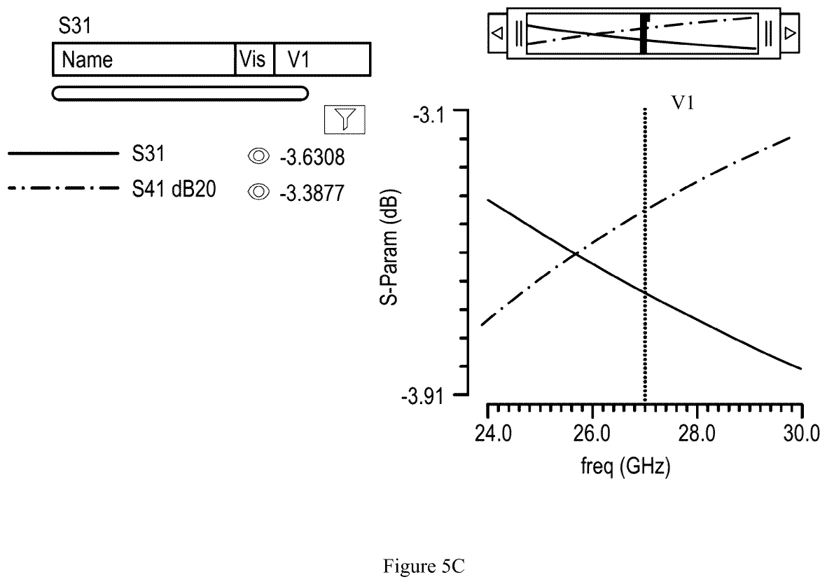

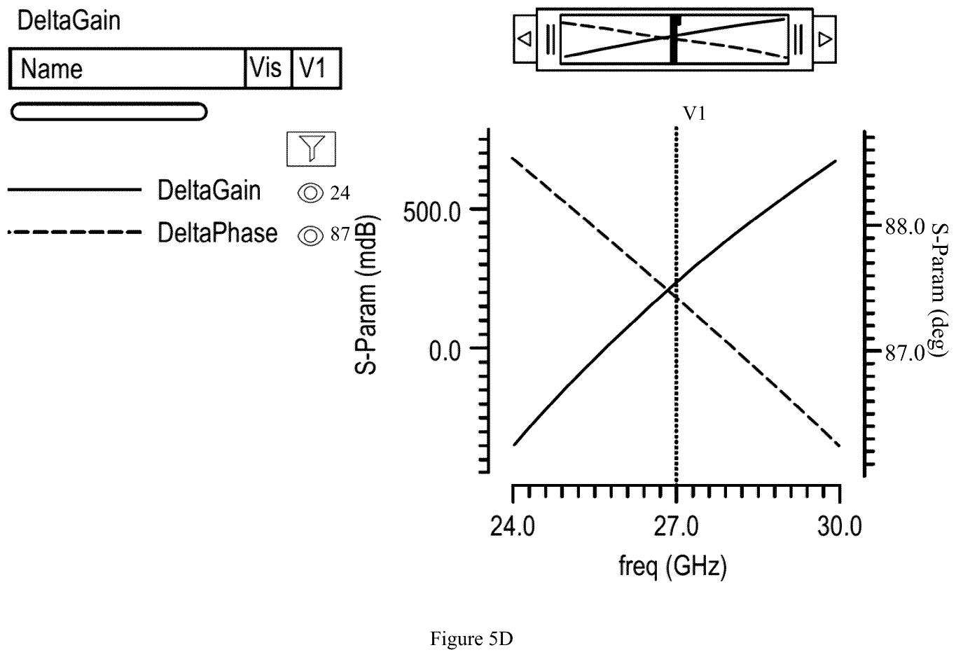

The embodiment of FIG. 3A is configured to have a differential impedance of 50-Ohms. The impedance can be managed by controlling the width and length of the traces. FIG. 5A, FIG. 5B, FIG. 5C, and FIG. 5D show small-signal S-parameter performance for an embodiment of the quadrature combiner. The layout was analyzed using a commercially available Electro-Magnetic (EM) simulator (Cadence Virtuoso from Cadence Design Systems) to generate the S-parameters. Return loss at each port is better than 12 dB, the loss is better than 0.5 dB, and there is good balance in the gain with a phase split of 87-degrees.

FIG. 3B schematically illustrates a side cutaway view of an embodiment of an integrated circuit balanced amplifier 300, having a semiconductor substrate layer 320, a first trace layer (or first “metal” layer) 330, a first via layer 340, a second trace layer (or second “metal” layer) 350, a third trace layer (or third “metal” layer) 360, a second via layer 370, and a fourth trace layer (or fourth “metal” layer) 380. As described in more detail below, FIG. 3C schematically illustrates circuit traces on the first trace layer 330; FIG. 3D schematically illustrates vias, each via extending from a trace on the first trace layer 330 to a corresponding trace on the second trace layer 350; FIG. 3E schematically illustrates circuit traces on the second trace layer 350; FIG. 3F schematically illustrates circuit traces on the third trace layer 360; FIG. 3G schematically illustrates vias, each via extending from a trace on the third trace layer 360 to a corresponding trace on the fourth trace layer 380; and FIG. 3H schematically illustrates circuit traces on the fourth trace layer 380.

The first trace layer 330 may be referred-to as a first “bridge” layer 330, and the fourth trace layer 380 may be referred-to as the second “bridge” layer 380. Illustrative embodiments include a dielectric layer sandwiched between the first “bridge” layer 330 and semiconductor substrate layer 320. Illustrative embodiments include an insulator layer 390 sandwiched between the second trace layer (or second “metal” layer) 350 and the third trace layer (or third “metal” layer) 360.

I Some embodiments include a semiconductor layer, an insulator layer, or both a semiconductor layer and an insulator layer between the second trace layer 350 and the third trace layer 360. Preferred embodiments do not have a via layer between the second trace layer 350 and the third trace layer 360, which mitigates the risk of shorting together the second trace layer 350 and the third trace layer 360, and the traces on the second trace layer 350 and the third trace layer 360.

In illustrative embodiments, a via layer (e.g., first via layer 340; second via layer 370) is composed of an insulator material having a first face, and a second face parallel to the first face. The via layer has metal vias extending completely through the insulator material from the first face to the second face. Each metal via is configured to conduct an RF signal from a trace on a layer on one side of its respective via layer (e.g., a first trace layer disposed on the first face of the insulator layer) to a trace in another layer on the other side (e.g., a second trace layer disposed on the second face of the insulator layer).

For example, via layer 340 has vias that connect traces on trace layer 330 to traces on trace layer 350, and via layer 370 vias that connect traces on trace layer 360 to traces on trace layer 380.

Some embodiments include a silicon-on-insulator base that includes an insulator substrate 310 supporting the semiconductor substrate layer 320 such that the semiconductor substrate layer 320 is sandwiched between the insulator substrate 310 and a trace layers (e.g., 330) and via layers (e.g., 340).

In illustrative embodiments, the second trace layer 350 has a surface (the second trace layer surface) that defines a plane (the second trace layer plane), and includes a plurality of traces in that plane, each of which traces is configured to conduct RF signals. The plurality of traces includes a plurality of 180-degree segments concentrically disposed around a center point 3501 of the second trace layer 350, along with additional traces. Each 180-degree segment may be described as being shaped like the letter “U” (or “U-shaped”), or as having the shape of a square bracket (“[”).

In illustrative embodiments, the plurality of traces include three 180-degree segments disposed on one side of the center point or center line bisecting the plane of the trace layer (which side may be referred to as the “left” side), and three additional 80-degree segments disposed on another side of the center point (which side may be referred to as the “right” side), such that the three segments on the left side of the center point face the three segments on the right side of the center point. Other embodiment may include two 180-degree segments disposed on the left side and two additional 180-degree segments disposed on the right side, depending on how much coupling is desired. Other embodiment may include more than three 180-degree segments disposed on the left side and more than three additional 80-degree segments disposed on the right side, depending on how much coupling is desired. In general, illustrative embodiments have the same number of 180-degree segments on the left side as on the right side.

In illustrative embodiments, the third trace layer 360 has a surface (the third trace layer surface) that defines a plane (the third trace layer plane), and includes a plurality of traces in that plane, each of which traces is configured to conduct RF signals. The plurality of traces includes a plurality of 180-degree segments concentrically disposed around a center point, along with additional traces. Each 180-degree segment may be described as being shaped like the letter “U” (or “U-shaped”), or as having the shape of a square bracket (“[”), and so may be referred-to as a U-trace.

FIG. 3E schematically illustrates traces on the surface 351 of trace layer 350. The plurality of traces include a first input trace 3510 and a second input trace 3520, which together form an input port 352 configured to receive a differential RF signal. The traces also include a left inner-most U-trace 3531, a left outermost U-trace 3535, and a left middle U-trace 3533 disposed between left inner-most U-trace 3531 and left outermost U-trace 3535.

The traces also include a right inner-most U-trace 3541, a right outermost U-trace 3545, and a right middle U-trace 3543 disposed between right innermost U-trace 3541 and right outermost U-trace 3545.

The left outermost U-trace 3535 also includes an output leg 3536, and the right outermost U-trace 3545 includes an output leg 3546 that form quadrature output port 354.

The first input trace 3510 is electrically coupled to the left inner-most U-trace 3531 by a first bridge trace 331 on first trace layer 330. The first bridge trace 331 is electrically coupled to the first input trace 3510 by via 341 in first via layer 340. The first bridge trace 331 is electrically coupled to the left inner-most U-trace 3531 by via 342 in the first via layer 340.

The left inner-most U-trace 3531 is electrically coupled to right middle U-trace 3543 by first diagonal trace 3536.

Right middle U-trace 3543 is electrically coupled to left outermost trace 3535 by second bridge trace 332 on first trace layer 330. The second bridge trace 332 is electrically coupled to the right middle U-trace 3543 by via 344 in first via layer 330. The second bridge trace 332 is electrically coupled to the left outermost trace 3535 by via 344 in first via layer 340.

The second input trace 3520 is electrically coupled to the right innermost U-trace 3541 by second bridge trace 333 on first trace layer 330. The second bridge trace 333 is coupled to second input trace 3520 by via 345 on first via layer 340, and is coupled to right innermost U-trace 3541 by via 346 on first via layer 340.

Right innermost U-trace 3541 is electrically coupled to left middle U-trace 3533 by third bridge trace 335 on first trace layer 330. The third bridge trace 335 is coupled to the innermost U-trace 3541 by via 347 on first via layer 340, and is coupled to left middle U-trace 3533 by via 348 on the first via layer 340.

Left middle U-trace 3533 is electrically coupled to right outermost U-trace 3545 by a second diagonal trace 3534.

The first trace layer 350 also includes a differential to single-ended balun structure 3570, having first balun trace 3571 coupled to left outermost U-trace 3535 by trace segment 3536 and via 3491 on first via layer 340. Balun 370 also includes a single-ended output terminal 372 coupled to fight outermost U-trace 3545 by trace segment 3546 and via 3492 on first via layer 340. In illustrative embodiments, the first balun trace 3571 is a U-shaped trace. In some embodiments, the first balun trace 3571 has a shape that is a rectangle, although not a completely closed rectangle.

Bridge structure 336 is electrically coupled to vias 3491 and 3492, as part of the output balun structure.

FIG. 3F schematically illustrates U-traces on the surface 361 of third U-trace layer 360. The plurality of U-traces includes a third input U-trace 3610 and a fourth input U-trace 3620, which together form an input port 362 configured to receive a differential RF signal. The U-traces also include a left inner-most U-trace 3631, a left outermost U-trace 3635, and a left middle U-trace 3633 disposed between left inner-most U-trace 3631 and left outermost U-trace 3635.

The U-traces also include a right inner-most U-trace 3641, a right outermost U-trace 3645, and a right middle U-trace 3643 disposed between right innermost U-trace 3641 and right outermost U-trace 3645. The right outermost U-trace 3645 is electrically coupled to the left middle U-trace 3633 by third diagonal U-trace 3634.

The third input U-trace 3610 is electrically coupled to the left outermost U-trace 3635 and the fourth input U-trace 3620 is electrically coupled to right outermost U-trace 3645.

The left middle U-trace 3633 is electrically coupled to the right innermost U-trace 3641 by bridge trace 381 on second bridge layer 380. Bridge trace 381 is electrically coupled to left middle U-trace 3633 by via 371 on via layer 370, and is electrically coupled to right innermost U-trace 3641 by via 372 on via layer 370.

Right innermost U-trace 3641 is electrically coupled to third output trace 3630 by bridge 382 on second bridge layer 380. Bridge 382 is electrically coupled to right innermost U-trace 3641 by via 373 on via layer 370, and is electrically coupled to third output trace 3630 by via 374 on via layer 370.

Left outermost U-trace 3635 is electrically coupled to right middle U-trace 3643 by bridge 385. Bridge 385 is coupled to left outermost U-trace 3635 by via 375 on via layer 370 and is coupled to right middle U-trace 3643 by via 376 on via layer 370.

Right middle U-trace 3643 is coupled to left innermost U-trace 3631 by fourth diagonal U-trace 3635.

Left innermost U-trace 3631 is electrically coupled to fourth output trace 3640 by bridge trace 381. Bridge trace 381 is coupled to left innermost U-trace 3631 by via 377 on via layer 370, and is coupled to the fourth output trace 3640 by via 378 on via layer 370. Third output trace 3630 and fourth output trace 3640 together form fourth output terminal 364.

Third U-trace layer 360 also includes a differential to single-ended balun structure 3670, having second balun trace 3671. In illustrative embodiments, the second balun trace 3671 is a U-shaped trace. In some embodiments, the first balun trace 3571 is a rectangle. In illustrative embodiments, the second balun trace 3671 is broadside coupled to the first balun trace 3571.

FIG. 4 schematically illustrates an embodiment of a differential to single-ended balun 420 which may be referred-to as an “output” balun coupled to a quadrature combiner circuit 300. The differential to single-ended balun 420 includes balun structures 3570 and 3670, and bridge structure 336 and vias 3491 and 3492. The “output” balun 420 is electrically coupled to the quadrature combiner circuit 300 and to the single-ended RF signal output 250, and is electrically disposed between the quadrature combiner circuit 300 and the single-ended RF signal output terminal 250.

The differential to single-ended balun input port 422 is in electrical communication with the quadrature output port 354 of the quadrature combiner circuit 300.

FIG. 5A shows the return loss from the 4 input ports S11, S22, S33, and S44. It also includes the isolation from the isolated port in trace S21 when port 1 is used as the input.

FIG. 5B shows the phase difference between the phases at ports 3 and 4 when port 1 is driven as the input. These show that the phases are approximately 90-degrees apart for quadrature performance. Please note that the circuit is reciprocal and will work in a similar manner is ports 3 and 4 are the inputs driven together 90-degrees out of phase. It is easier to analyze it this way as S-parameters are best suited to 2-port analysis.

FIG. 5C shows the gain (loss) at ports 3 and 4 when port 1 is used as the input. These would both ideally be −3 dB for a perfect split but are less due to the loss in the metal traces.

FIG. 5D shows the difference in phase and amplitude between ports 3 and 4. These are very close to the desired values of 0 and 90-degrees, respectively.

In illustrative embodiments, the quadrature combiner circuit 300 has a differential input port (an “in-phase” input port) for an in-phase differential signal, which in-phase differential signal has a positive in-phase component and a negative in-phase component. The quadrature combiner circuit 300 has a differential input port (a “quadrature” input port) for a quadrature differential signal, which quadrature differential signal has a positive quadrature component and a negative quadrature component. Each signal component has a corresponding signal path defined by traces, vias and bridge structures in the quadrature combiner circuit 300. For example, the positive in-phase component has a corresponding positive in-phase signal path, and the negative in-phase component has a corresponding negative in-phase signal path. Similarly, the positive quadrature component has a corresponding positive quadrature signal path, and the negative quadrature component has a corresponding negative quadrature signal path.

Each such signal path forms a coiled, or spiral, signal path around a center point of the quadrature combiner circuit 300.

As schematically illustrated, each coiled, or spiral, signal path is broadside coupled to another such signal path to produce capacitive coupling between the respective signal paths, while desirably limiting the size of the quadrature combiner circuit 300, and desirably enhancing the ability for an RF engineer to design such a circuit to the exacting tolerances required for an RF combiner circuit 300 in a balanced amplifier 200.

In illustrative embodiments, each such signal path makes 1.5 turns around a center axis (a line passing through a center point on each trace layer) before exiting the quadrature combiner circuits.

For example, one signal path from port 352 includes U-traces 3531, 3543 and 3535, which makes 1.5 counterclockwise turns about the center point of layer 350. Its differential counterpart from port 352 includes U-traces 3541, 3533 and 3545, which makes 1.5 clockwise turns about the center point 3501 of layer 350.

Similarly, one signal path from port 362 includes U-traces 3635, 3643, and 3631 which makes 1.5 clockwise turns about the center point 3601 of layer 360. Its differential counterpart from port 362 includes U-traces 3645, 3633 and 3541, which makes 1.5 counterclockwise turns about the center point 3601 of layer 360.

Note that U-trace 3535 is broadside coupled to U-trace 3635; U-trace 3533 is broadside coupled to U-trace 3633; U-trace 3531 is broadside coupled to U-trace 3631; U-trace 3541 is broadside coupled to U-trace 3641; U-trace 3543 is broadside coupled to U-trace 3643; and U-trace 3545 is broadside coupled to U-trace 3645. Consequently, the configuration of U-traces in quadrature combiner 300 provides more opportunity to create exacting capacitive coupling required for an RF combiner circuit 300 in a balanced amplifier 200, and provides more opportunity to create such capacitive coupling than conventional RF combiner circuits.

Other embodiments may include signal paths of lengths configured to make more than 1.5 turns around the center axis. Such longer lengths provide the circuit designer the opportunity to desirably add impedance between coupled traces. Consequently, embodiment of quadrature combiner circuit 300 may be described has having four concentric spiral signal paths, wherein each spiral signal path makes at least 1.5 turns around a common center axis.

In general, the balanced amplifier 200 can be configured to operate over a wide range of radio frequencies. Configuring the balanced amplifier 200 to operate at a desired frequency, or desired band of frequencies, includes carefully establishing and manufacturing the traces of the quadrature combiner circuit 300 to establish trace lengths and impedances (e.g., inductance; edge-coupling capacitance; broadside-coupling capacitance) to create a 90 degree phase difference between an in-phase signal and a quadrature signal.

Values of such impedances will depend on the frequency, or band of frequencies, for which the quadrature combiner 300 is to be used. Moreover, such impedances may be established by establishing or varying one or more of inductance, edge-coupling capacitance, and/or broadside-coupling capacitance in the traces of the quadrature combiner. Configuring the quadrature combiner circuit 300 may be accomplished by an engineer experienced in RF circuit design, having possession of this specification, and using commercially-available RF simulation software (e.g., Cadence Virtuoso from Cadence Design Systems).

For example, using Cadence Virtuoso from Cadence Design Systems, the inventors were able to configure some embodiments of the quadrature combiner circuit 300 to perform the combiner functions described above over a band of 8 GHz to 8 GHz+20% (8 GHz to 9.6 GHz), and in other embodiments in a band of 80 GHz−20% (64 GHz to 80 GHz). Some embodiments of the quadrature combiner circuit 300 (and the balanced amplifier in which or with which the combiner circuit 300 is used) are configured to operate on differential signals having a frequency greater than 2.9 GHz.

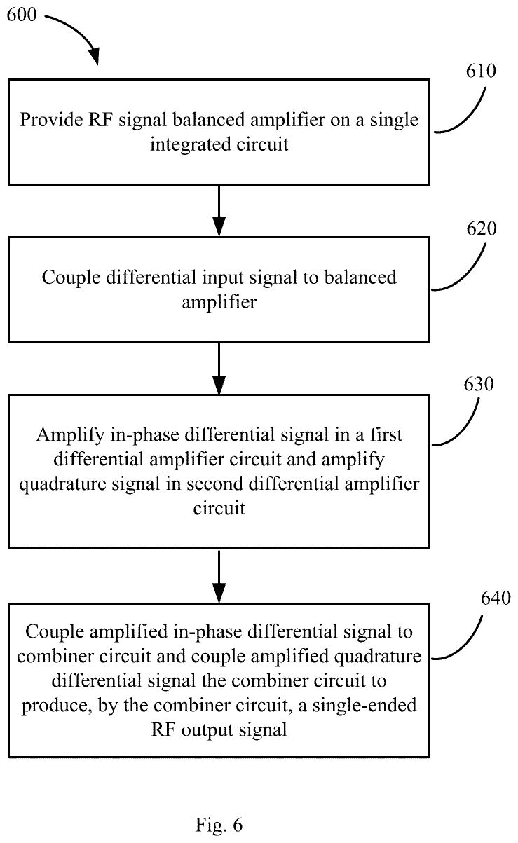

FIG. 6 is a flowchart illustrating a method 600 for processing a differential radiofrequency input signal.

At step 610, the method includes providing integrated circuit radio frequency signal balanced amplifier 300. Such a balanced amplifier may include a unitary substrate; a multi-layer integrated circuit fabricated on the unitary substrate. The multi-layer integrated circuit includes a plurality of circuit elements all on the unitary substrate, including a differential input circuit having: a differential input port; a quadrature splitter circuit having a differential input electrically coupled to the differential input port, a first differential output and a second differential output, the quadrature circuit integrated on a plurality of layers of the multi-layer integrated circuit and configured to produce a direct differential signal on the first differential output and a coupled differential signal on the second differential output, the coupled differential signal in quadrature with the direct output signal.

The multi-layer integrated circuit also includes a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal. The multi-layer integrated circuit also includes a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal.

The multi-layer integrated circuit also includes a quadrature combiner circuit including: a first differential quadrature combiner input port coupled to the first amplifier differential output to receive the first differential output signal; and a second differential quadrature combiner input port coupled to the second amplifier differential output to receive the second differential output signal; and a differential quadrature combiner output port. The quadrature combiner circuit is configured to combine the first differential output signal and the second differential output signal into a single differential combined RF signal.

The integrated circuit also includes a differential to single-ended output balun having an output balun differential input coupled to the differential quadrature combiner output port; to receive the differential combined RF signal, the differential to single-ended output balun configured to produce, from the differential combined RF signal, a single-ended RF output signal. Said balun also including a single-ended output port in electrical communication with the differential to single-ended output balun to receive the single-ended RF output signal.

At step 620, the method 600 includes coupling an input differential radiofrequency signal to the differential input port of the differential input circuit, to produce, by the differential input circuit, an in-phase differential signal and a quadrature differential signal.

At step 630, the method 600 includes amplifying the in-phase differential signal in the first differential amplifier circuit to produce an amplified in-phase differential signal, and amplifying the quadrature differential signal in the second differential amplifier circuit to produce an amplified quadrature differential signal.

At step 640, the method 600 includes coupling the amplified in-phase differential signal to the combiner circuit and coupling the amplified quadrature differential signal the combiner circuit to produce, by the combiner circuit, a single-ended RF output signal.

Some embodiments also include, at step 610, processing the input differential radiofrequency signal with digital predistortion prior to coupling the input differential radiofrequency signal to the differential input port of the differential input circuit.

In some embodiments, the quadrature combiner circuit further includes a first differential termination output port.

In some embodiments, the quadrature combiner circuit further includes a combiner circuit differential termination output port.

In some embodiments, the differential to single-ended output balun is not a transformer.

In some embodiments, the integrated circuit radio frequency signal amplifier is sealed within a single unitary integrated circuit package.

Although the embodiment of FIG. 3B shows layers 330, 340 and 350 disposed between layer 320 and layers 360, 370 and 380, other embodiments dispose layers 360, 370 and 380 between layer 320 and layers 330, 340 and 350.

The in-phase terminal for the quadrature combiner (or splitter) may be at the same phase as the combined (or input port), or have an arbitrary delay from this reference phase. The quadrature terminal must have the same delay as the in-phase port in order to keep the 90-degree separation from the in-phase port. This delay is assumed to be 0 for the majority of this text, but any arbitrary delay will not adversely impact the functionality provided it is equal on both the in-phase and quadrature terminals.

A listing of certain reference numbers is presented below.
100: traditional amplifier circuit;
200: compact balanced integrated circuit differential amplifier;
201: Unitary substrate;
210: Differential RF signal input port;
212: Input termination port;
214: Output termination impedance;
220: Input quadrature circuit;
230: First amplifier circuit;
240: Second amplifier circuit;
250: Single-ended RF signal output terminal;
252: Output termination port;
254: Output termination impedance;
260: Integrated circuit package;
300: Quadrature combiner circuit;
310: Insulator layer;
320: Semiconductor substrate;
330: First trace layer (or first “bridge” layer);
340: First via layer;
350: Second trace layer;
352: First differential quadrature combiner input;
360: Third trace layer;
362: Second differential quadrature combiner input;
370: Second via layer;
380: Fourth trace layer (or second “bridge” layer);
390: Insulator layer;
3501: Center point of the second trace layer 350;
3601: Center point of the second trace layer 360

Various embodiments may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

Without limitation, potential subject matter that may be claimed (prefaced with the letter “P” so as to avoid confusion with the actual claims presented below) includes:
P1. An integrated circuit radio frequency signal amplifier comprising:
   a unitary substrate;
   a multi-layer integrated circuit fabricated on the unitary substrate, the multi-layer integrated circuit comprising a plurality of circuit elements all on the unitary substrate, the plurality of circuit elements comprising:
      a differential input circuit comprising:
      a differential input port;
   a quadrature combiner circuit having a differential input electrically coupled to the differential input port, a first differential output and a second differential output, the quadrature combiner circuit integrated on a plurality of layers of the multi-layer integrated circuit and configured to produce a direct differential signal on the first differential output and a coupled differential signal on the second differential output, the coupled differential signal in quadrature with the direct output signal;
   a first differential amplifier circuit having a first amplifier differential input in electrical communication with the first differential output of the quadrature combiner circuit, and a first amplifier differential output, the first differential amplifier circuit configured to produce, at the first amplifier differential output, a first differential output signal;
   a second differential amplifier circuit having a second amplifier differential input in electrical communication with the second differential output of the quadrature combiner circuit, and a second amplifier differential output, the second differential amplifier circuit configured to produce, at the second amplifier differential output, a second differential output signal in quadrature with the first differential output signal; and
      a quadrature combiner circuit comprising:
      a first differential quadrature combiner input port coupled to the first amplifier differential output to receive the first differential output signal; and
      a second differential quadrature combiner input port coupled to the second amplifier differential output to receive the second differential output signal;
   a differential quadrature combiner output port;
   the combiner circuit configured to combine the first differential output signal and the second differential output signal into a single differential combined RF signal, and
   a differential to single-ended output balun having an output balun differential input coupled to the differential quadrature combiner output port; to receive the differential combined RF signal, the differential to single-ended output balun configured to produce, from the differential combined RF signal, a single-ended RF output signal;
   a single-ended output port in electrical communication with the differential to single-ended output balun to receive the single-ended RF output signal.

The embodiments described above are intended to be merely exemplary; numerous variations and modifications will be apparent to those skilled in the art. All such variations and modifications are intended to be within the scope of the present disclosure as defined in any appended claims.

What is claimed is:

1. An integrated circuit radio frequency signal amplifier comprising:
a multi-layer integrated circuit fabricated on a unitary substrate, the multi-layer integrated circuit comprising a plurality of circuit elements all on the unitary substrate, the plurality of circuit elements comprising:
a differential input circuit comprising:
a differential input port;
a quadrature splitter circuit having a differential input electrically coupled to the differential input port, a first differential output and a second differential output, the quadrature splitter configured to produce an in-phase differential signal on the first differential output and a quadrature differential signal on the second differential output, the quadrature differential signal in quadrature with the in-phase output signal;
a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal;
a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal; and
a quadrature combiner circuit comprising:
a first differential quadrature combiner input port coupled to the first amplifier differential output to receive the first differential output signal; and
a second differential quadrature combiner input port coupled to the second amplifier differential output to receive the second differential output signal;
a differential quadrature combiner output port;
the combiner circuit configured to combine the first differential output signal and the second differential output signal into a single differential combined RF signal, and
a differential to single-ended output balun having an output balun differential input coupled to the differential quadrature combiner output port to receive the differential combined RF signal, the differential to single-ended output balun configured to produce, from the differential combined RF signal, a single-ended RF output signal;
a single-ended output port in electrical communication with the differential to single-ended output balun to receive the single-ended RF output signal.

2. The integrated circuit radio frequency signal amplifier of claim 1, wherein the quadrature splitter circuit further comprises a first differential termination output port.

3. The integrated circuit radio frequency signal amplifier of claim 1, wherein the combiner circuit further comprises a combiner circuit differential termination output port.

4. The integrated circuit radio frequency signal amplifier of claim 1, wherein the differential to single-ended output balun is not a transformer.

5. The integrated circuit radio frequency signal amplifier of claim 1, further comprising a unitary integrated circuit package, the unitary substrate and the plurality of circuit elements sealed within the unitary integrated circuit package.

6. The integrated circuit radio frequency signal amplifier of claim 1, wherein the unitary substrate comprises a silicon substrate.

7. The integrated circuit radio frequency signal amplifier of claim 1, wherein the unitary substrate comprises a silicon-on-insulator substrate.

8. A method of processing a differential radiofrequency input signal, the method comprising:
providing integrated circuit radio frequency signal balanced amplifier comprising:
a multi-layer integrated circuit fabricated on a unitary substrate, the multi-layer integrated circuit comprising a plurality of circuit elements all on the unitary substrate, the plurality of circuit elements comprising:
a differential input circuit comprising:
a differential input port;
a quadrature splitter circuit having a differential input electrically coupled to the differential input port, a first differential output and a second differential output, the quadrature splitter circuit configured to produce an in-phase differential signal on the first differential output and a quadrature differential signal on the second differential output, the in-phase differential signal in quadrature with the direct quadrature signal;
a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal;
a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal; and
a quadrature combiner circuit comprising:
a first differential quadrature combiner input port coupled to the first amplifier differential output to receive the first differential output signal; and
a second differential quadrature combiner input port coupled to the second amplifier differential output to receive the second differential output signal;
a differential quadrature combiner output port;
the quadrature combiner circuit configured to combine the first differential output signal and the second differential output signal into a single differential combined RF signal, and
a differential to single-ended output balun having an output balun differential input coupled to the differential quadrature combiner output port to receive the differential combined RF signal, the differential to single-ended output balun configured to produce, from the differential combined RF signal, a single-ended RF output signal;
a single-ended output port in electrical communication with the differential to single-ended output balun to receive the single-ended RF output signal;
coupling an input differential radiofrequency signal to the differential input port of the differential input circuit, to produce, by the differential input circuit, the in-phase differential signal and the quadrature differential signal;
amplifying the in-phase differential signal in the first differential amplifier circuit to produce an amplified in-phase differential signal;
amplifying the quadrature differential signal in the second differential amplifier circuit to produce an amplified quadrature differential signal;
coupling the amplified in-phase differential signal to the combiner circuit and coupling the amplified quadrature differential signal the combiner circuit to produce, by the combiner circuit, a single-ended RF output signal.

9. The method of claim 8, further comprising processing the input differential radiofrequency signal with digital predistortion prior to coupling the input differential radiofrequency signal to the differential input port of the differential input circuit.

10. The method of claim 8, wherein: the quadrature splitter circuit further comprises a first differential termination output port.

11. The method of claim 8, wherein: the combiner circuit further comprises a combiner circuit differential termination output port.

12. The method of claim 8, wherein: differential to single-ended output balun is not a transformer.

13. The method of claim 8, wherein: the integrated circuit radio frequency signal amplifier is sealed within a single unitary integrated circuit package.

14. The method of claim 8, wherein: the unitary substrate comprises a silicon substrate.

15. The method of claim 8, wherein: wherein the unitary substrate comprises a silicon-on-insulator substrate.

16. An apparatus comprising:
a multi-layer integrated circuit fabricated on a unitary substrate, the multi-layer integrated circuit comprising a plurality of circuit elements all on the unitary substrate, the plurality of circuit elements comprising:
a differential input circuit comprising:
a differential input port;
a quadrature splitter circuit having a differential input electrically coupled to the differential input port, a first differential output and a second differential output, the quadrature splitter circuit integrated on a plurality of layers of the multi-layer integrated circuit and configured to produce an in-phase differential signal on the first differential output and a quadrature differential signal on the second differential output, the quadrature differential signal in quadrature with the in-phase output signal;
a first differential amplifier circuit having a first amplifier differential input in electrical communication with the first differential output of the quadrature splitter circuit, and a first amplifier differential output, the first differential amplifier circuit configured to produce, at the first amplifier differential output, a first differential output signal;
a second differential amplifier circuit having a second amplifier differential input in electrical communication with the second differential output of the quadrature splitter circuit, and a second amplifier differential output, the second differential amplifier circuit configured to produce, at the second amplifier differential output, a second differential output signal in quadrature with the first differential output signal; and
combiner means for producing a single differential combined RF signal from the first differential output signal and the second differential output signal;
means for producing, from the differential combined RF signal, a single-ended RF output signal; and
a single-ended output port in electrical communication with the differential to single-ended output balun to receive the single-ended RF output signal.

17. The apparatus of claim 16, wherein: the means for producing, from the differential combined RF signal, a single-ended RF output signal is not a transformer.

18. The apparatus of claim 16, wherein: the quadrature combiner means comprises a first differential termination output port.

19. The apparatus of claim 16, wherein: wherein the unitary substrate comprises a silicon substrate.

20. The apparatus of claim 16, wherein: the unitary substrate and the multi-layer integrated circuit are sealed within a single unitary integrated circuit package.
